(19) United States
(12) Patent Application Publication
(10) Pub. No.: US 2026/0293032 A1
(43) Pub. Date: Sep. 24, 2026

(54) QUICK-RELEASE MOUNTING ACCESSORIES FOR COMPUTER CHASSIS

(71) Applicant: QUANTA COMPUTER INC., Taoyuan City (TW)

(72) Inventors: Yaw-Tzorng TSORNG, Taoyuan City (TW); Ming-Lung WANG, Taoyuan City (TW); Wei-Kang TSAI, Taoyuan City (TW); Pei-Jung HSIEH, Taoyuan City (TW)

(21) Appl. No.: 19/083,282

(22) Filed: Mar. 18, 2025

(51) Int. Cl. H05K 7/14

(52) U.S. Cl. CPC H05K 7/1489; H05K 7/1407

(57) ABSTRACT

A computer chassis with detachable, quick-release mounting brackets is disclosed. The mounting brackets attach to a chassis by inserting a stud of the bracket into a corresponding opening of the chassis. An outwardly biased detent near the distal end of each stud retracts as the stud is inserted into the stud opening, then rebounds outwards after the stud is fully inserted to retain the mounting bracket against the computer chassis. The mounting bracket is easily removed and re-attached by hand by pulling the mounting bracket away from the computer chassis. Once mounting brackets attached to a computer chassis are secured to mounting posts (e.g., posts of a computer rack), they can no longer be moved away from the chassis, thus ensuring the mounting brackets remain secured to the chassis at least until the mounting brackets are uncoupled from the mounting posts.

### TECHNICAL FIELD

The present disclosure relates to computing hardware generally and more specifically to chassis mounting hardware.

### BACKGROUND

Mountable (e.g., rack-mountable) computing devices are generally designed with fixed-position mounting accessories, often in the form of brackets near the front of the computer chassis. These brackets, which are often welded or rivetted to the computer chassis, are used to secure the chassis in a mounting slot of a rack system.

The fixed nature of these types of mounting accessories, however, makes them susceptible to damage during packaging and transportation. Further, more complex and costly packaging may be required to ensure these mounting accessories are not damaged during transportation. Also, the fixed nature of these mounting accessories limits how the chassis can be mounted on a rack system and what types (e.g., depths) of rack systems can be used.

### BRIEF SUMMARY

The term embodiment and like terms, e.g., implementation, configuration, aspect, example, and option, are intended to refer broadly to all of the subject matter of this disclosure and the claims below. Statements containing these terms should be understood not to limit the subject matter described herein or to limit the meaning or scope of the claims below. Embodiments of the present disclosure covered herein are defined by the claims below, not this summary. This summary is a high-level overview of various aspects of the disclosure and introduces some of the concepts that are further described in the Detailed Description section below. This summary is not intended to identify key or essential features of the claimed subject matter. This summary is also not intended to be used in isolation to determine the scope of the claimed subject matter. The subject matter should be understood by reference to appropriate portions of the entire specification of this disclosure, any or all drawings, and each claim.

According to certain implementations of the present disclosure, a chassis mounting bracket includes a bracket body having a front wall and a side wall. The side wall includes a chassis-contacting face. The chassis mounting bracket further includes an aperture in the front wall for receiving a mounting screw. The chassis mounting bracket further includes a plurality of studs extending from the chassis-contacting face in a lateral direction that is perpendicular to the chassis-contacting face, each of the plurality of studs having a detent movable between a retracted position and an extended position, the detent being biased towards the extended position.

In some cases, the chassis mounting bracket further includes a guide slot in the side wall for receiving a guide flange of a chassis. The guide slot is positioned with respect to the plurality of studs such that when the guide slot is aligned to receive the guide flange of the chassis each of the plurality of studs is aligned to be received by corresponding stud openings in the chassis. In some cases, the plurality of studs includes a first stud extending from a top half of the chassis-contacting face of the side wall and a second stud extending from a bottom half of the chassis-contacting face of the side wall. In some cases, the plurality of studs includes a first stud extending from a front half of the chassis-contacting face of the side wall and a second stud extending from a rear half of the chassis-contacting face of the side wall. In some cases, each detent of the plurality of studs moves between the retracted position and the extended position along a retraction direction that is perpendicular to the lateral direction.

In some cases, at least one stud of the plurality of studs includes a second detent movable between a second retracted position and a second extended position, the second detent being biased towards the second extended position. In some cases, the detent and the second detent are arranged colinearly. In some cases, the detent is a ball detent. In some cases, the detent is spring-biased towards the extended position. In some cases, the mounting screw is captively secured within the aperture. In some cases, each detent is shaped to move to the retracted position when contacting a periphery of a stud opening in a chassis and return to the extended position when fully inserted within the stud opening.

According to certain implementations of the present disclosure, a computer chassis mounting system can include a computer chassis having a first sidewall opposite a second sidewall. A first mounting location of the computer chassis can have a first set of mounting apertures in the first sidewall positioned opposite a corresponding second set of mounting apertures in the second sidewall. The computer chassis mounting system can further include a pair of chassis mounting brackets. Each of the pair of chassis mounting brackets is the chassis mounting bracket described above. A first chassis mounting bracket of the pair of chassis mounting brackets is coupled to the computer chassis at the first set of mounting apertures and a second chassis mounting bracket of the pair of chassis mounting brackets is coupled to the computer chassis at the second set of mounting apertures.

In some cases, the computer chassis mounting system further includes a first mounting post and a second mounting post. Each of the first mounting post and the second mounting post include a plurality of corresponding vertically spaced-apart apertures. The mounting screw of the first chassis mounting bracket is coupled to the first mounting post at a first aperture of the plurality of vertically spaced-apart apertures, and the mounting screw of the second chassis mounting bracket is coupled to the second mounting post at a second aperture of the plurality of vertically spaced-apart apertures. The first aperture and the second aperture are at an equal height.

In some cases, the computer chassis mounting system further includes a second mounting location of the computer chassis spaced apart from the first mounting location. The second mounting location includes a third set of mounting apertures in the first sidewall positioned opposite a corresponding fourth set of mounting apertures in the second sidewall. In some cases, the second mounting location is positioned between a front wall of the computer chassis and the first mounting location.

According to certain implementations of the present disclosure, a method for mounting a computer chassis is disclosed. A computer chassis including a left sidewall opposite a right sidewall, and a first mounting location having a left set of mounting apertures in the left sidewall positioned opposite a corresponding right set of mounting apertures in the right sidewall is provided. The method further includes providing a left chassis mounting bracket and a right chassis mounting bracket. Each of the left chassis mounting bracket and the right chassis mounting bracket include: (i) a bracket body having a front wall and a side wall, the side wall having a chassis-contacting face; (ii) an aperture in the front wall for receiving a mounting screw; and (iii) a plurality of studs extending from the chassis-contacting face in a lateral direction that is perpendicular to the chassis-contacting face. Each of the plurality of studs includes a detent movable between a retracted position and an extended position. The detent is biased towards the extended position. The method further includes coupling the left chassis mounting bracket to the left sidewall of the computer chassis at the first mounting location by inserting the plurality of studs of the left chassis mounting bracket into the left set of mounting apertures. The method further includes coupling the right chassis mounting bracket to the right sidewall of the computer chassis at the first mounting location by inserting the plurality of studs of the right chassis mounting bracket into the right set of mounting apertures.

In some cases, inserting the plurality of studs of the left chassis mounting bracket into the left set of mounting apertures and inserting the plurality of studs of the right chassis mounting bracket into the right set of mounting apertures each includes, for each stud of the respective plurality of studs, retracting the respective detent to the retracted position in response to contacting the respective detent with a respective periphery of the respective mounting aperture during initial insertion of the respective stud into the respective mounting aperture, and returning the respective detent to the extended position in response to fully inserting the respective stud into the respective mounting aperture.

In some cases, the first mounting location further includes a left guide flange and a right guide flange. The left chassis mounting bracket includes a left guide slot. The right chassis mounting bracket includes a right guide slot. Inserting the plurality of studs of the left chassis mounting bracket into the left set of mounting apertures includes aligning the left guide flange with the left guide slot, and inserting the plurality of studs of the right chassis mounting bracket into the right set of mounting apertures includes aligning the right guide flange with the right guide slot.

In some cases, the computer chassis further includes a second mounting location having a second left set of mounting apertures in the left sidewall positioned opposite a corresponding second right set of mounting apertures in the right sidewall. The method further includes removing the left chassis mounting bracket from the left sidewall of the computer chassis and removing the right chassis mounting bracket from the right sidewall of the computer chassis. The method further includes coupling the left chassis mounting bracket to the left sidewall of the computer chassis at the second mounting location by inserting the plurality of studs of the left chassis mounting bracket into the second left set of mounting apertures; and coupling the right chassis mounting bracket to the right sidewall of the computer chassis at the second mounting location by inserting the plurality of studs of the right chassis mounting bracket into the second right set of mounting apertures.

In some cases, the left chassis mounting bracket includes a left captive screw, and the right chassis mounting bracket includes a right captive screw. In some cases, the method further includes mounting the chassis to a structure. The structure supports a left mounting post and a right mounting post. Mounting the chassis to the structure includes securing the left chassis mounting bracket to the left mounting post via the left captive screw and securing the right chassis mounting bracket to the right mounting post via the right captive screw.

The above summary is not intended to represent each embodiment or every aspect of the present disclosure. Rather, the foregoing summary merely provides an example of some of the novel aspects and features set forth herein. The above features and advantages, and other features and advantages of the present disclosure, will be readily apparent from the following detailed description of representative embodiments and modes for carrying out the present invention, when taken in connection with the accompanying drawings and the appended claims. Additional aspects of the disclosure will be apparent to those of ordinary skill in the art in view of the detailed description of various embodiments, which is made with reference to the drawings, a brief description of which is provided below.

### BRIEF DESCRIPTION OF THE DRAWINGS

The disclosure, and its advantages and drawings, will be better understood from the following description of representative embodiments together with reference to the accompanying drawings. These drawings depict only representative embodiments, and are therefore not to be considered as limitations on the scope of the various embodiments or claims.

FIG. 1 is an isometric view of a chassis with quick-release mounting brackets in a forward mounting location, according to certain aspects of the present disclosure.

FIG. 2 is a top view of a chassis with quick-release mounting brackets in a forward mounting location, according to certain aspects of the present disclosure.

FIG. 3 is an isometric view of a chassis with quick-release mounting brackets in a second mounting location, according to certain aspects of the present disclosure.

FIG. 4 is an isometric view of a quick-release mounting bracket, according to certain aspects of the present disclosure.

FIG. 5 is a partial view of a stud of a quick-release mounting bracket, according to certain aspects of the present disclosure.

FIG. 6 is a cutaway side view of the stud of FIG. 5 taken along line 6:6, according to certain aspects of the present disclosure.

FIG. 7 is an isometric partial view of a quick-release mounting bracket aligned for insertion into a chassis, according to certain aspects of the present disclosure.

FIG. 8 is an axonometric partial view of the mounting bracket of FIG. 7 with studs initially inserted into the chassis, according to certain aspects of the present disclosure.

FIG. 9 is a cutaway top view of stud of FIG. 8 taken along line 9:9, according to certain aspects of the present disclosure.

FIG. 10 is an axonometric partial view of the quick-release mounting bracket of FIG. 8 substantially inserted into the chassis, according to certain aspects of the present disclosure.

FIG. 11 is a cutaway top view of the stud of FIG. 10 taken along line 11:11, according to certain aspects of the present disclosure.

FIG. 12 is a side view of the mounting bracket of FIG. 10 after the studs have been fully inserted into the chassis, according to certain aspects of the present disclosure.

FIG. 13 is a cutaway top view of the stud of FIG. 12 taken along line 13:13, according to certain aspects of the present disclosure.

FIG. 14 is a flowchart depicting a process for using quick-release mounting brackets with a computer chassis, according to certain aspects of the present disclosure.

### DETAILED DESCRIPTION

Embodiments of the present disclosure include a computer chassis with detachable, quick-release mounting brackets. The mounting brackets attach to the computer chassis by insertion of a stud of the bracket into a corresponding stud opening of the chassis. An outwardly biased detent near the distal end of each stud can be retracted (e.g., via compression) as the stud is being inserted into the stud opening, then can rebound outwards after the stud is fully inserted to help retain the mounting bracket against the computer chassis. The mounting bracket can be easily removed and re-attached by hand without the need of additional tools simply by pulling the mounting bracket away from the computer chassis perpendicular to the sidewall of the computer chassis. Once mounting brackets attached to a computer chassis are secured to mounting posts (e.g., posts of a computer rack), they can no longer be moved in that perpendicular direction, thus ensuring the mounting brackets remain secured to the computer chassis at least until the mounting brackets are uncoupled from the mounting posts.

The use of detachable mounting brackets like these allows for a computer chassis to be packaged and shipped much more efficiently, as there are no longer mounting brackets sticking out of the sides of the chassis. Rather, the mounting brackets can be packaged and shipped in a more convenient location (e.g., within the chassis itself) or in an otherwise more convenient fashion (e.g., boxes of mounting brackets can be packaged and shipped together to be used on any suitable chassis as needed).

Further, the detachable nature of the mounting brackets allows for relocation of the mounting brackets to different mounting locations on the chassis. For example, a chassis may have a standard mounting location (e.g., near the front of the chassis) and multiple additional mounting locations along the sidewall between the front and rear of the chassis. The positions of these mounting locations can be based on any suitable factor, such as dimensions of standard enclosures (e.g., mounting locations associated with a standard depth between a mounting post and a rear wall that would allow the chassis to be mounted without hitting the rear wall), weight distribution within the chassis (e.g., mounting locations located at or near a center of gravity of the chassis), or other case-specific factors (e.g., mounting locations located near a rear of the chassis to permit reverse-mounting the chassis or to permit mounting on mounting posts positioned very close to a rear wall). A user can easily and quickly customize how they mount the chassis by inserting the chassis mounting brackets into the appropriate holes at the desired mounting location. The user can quickly and easily remove the chassis mounting brackets and move them to different mounting locations, all without needing to use any tools.

Such quick-release, detachable mounting brackets can be especially useful for edge computing equipment, such as 5G edge servers and equipment. Edge computing equipment, by its nature, is often distributed in large numbers across many disparate locations. As such, this equipment is often housed in smaller enclosures that may be built specifically for housing the edge computing equipment and/or built to fit an existing space or other location-based requirement. Mounting edge equipment in non-standard enclosures may therefore require custom chassis, reworking of the enclosure space, or other complex or improvised solutions. By contrast, the use of quick-release, detachable mounting brackets allows a user to quickly select the best mounting location for the chassis and insert, by hand, the mounting brackets accordingly. For example, if a small enclosure provides only 14 inches of clearance between the mounting posts and the rear wall, a chassis that is 20 inches in depth can still be easily mounted by placing the mounting brackets at a mounting location at least 6 inches away from the front of the chassis. Further, the quick-release, detachable mounting brackets allow a user to customize the mounting location for a chassis on-the-fly without the need for tools, thus being able to nimbly navigate last-minute changes or relocation of equipment where different mounting depths would be desired.

While described herein as quick-release mounting brackets and shown in a particular style, in some cases other mounting accessories can be used in a similar fashion. For example, a cable management accessory may be detachably couplable to the computer chassis at an otherwise unused mounting location via a quick-release mounting accessory with compatible studs. As another example, a quick-release mounting accessory may take the form of sliding rails, allowing the rails to be coupled to the chassis at different depths, then permitting the chassis to be pulled out and pushed in along the rails (e.g., like a drawer). Other mounting accessories can be used.

Examples of quick-release mounting brackets are disclosed herein for single unit (1U) chassis. In some cases, multi-unit chassis (e.g., 2U, 4U, etc.) can be mounted using multiple quick-release mounting brackets (e.g., two 1U brackets for each side of a 2U chassis) or using a single, larger quick-release mounting bracket (e.g., a single 2U bracket for each side of the 2U chassis). Larger quick-release mounting brackets can have any suitable number of studs. In some cases, a multi-unit quick-release mounting bracket is equivalent to multiple single-unit quick-release mounting brackets stacked on top of one another.

Various embodiments are described with reference to the attached figures, where like reference numerals are used throughout the figures to designate similar or equivalent elements. Each reference numeral identifies the figure in which the reference numeral first appears, based on the first digit (for three-digit reference numerals) or the first two digits (for four-digit reference numerals) corresponding to the figure numeral of the figure. The figures are not necessarily drawn to scale and are provided merely to illustrate aspects and features of the present disclosure. Numerous specific details, relationships, and methods are set forth to provide a full understanding of certain aspects and features of the present disclosure, although one having ordinary skill in the relevant art will recognize that these aspects and features can be practiced without one or more of the specific details, with other relationships, or with other methods. In some instances, well-known structures or operations are not shown in detail for illustrative purposes. The various embodiments disclosed herein are not necessarily limited by the illustrated ordering of acts or events, as some acts may occur in different orders and/or concurrently with other acts or events. Furthermore, not all illustrated acts or events are necessarily required to implement certain aspects and features of the present disclosure.

For purposes of the present detailed description, unless specifically disclaimed, and where appropriate, the singular includes the plural and vice versa. The word “including” means “including without limitation.” Moreover, words of approximation, such as “about,” “almost,” “substantially,” “approximately,” and the like, can be used herein to mean “at,” “near,” “nearly at,” “within 3-5% of,” “within acceptable manufacturing tolerances of,” or any logical combination thereof. Similarly, terms “vertical” or “horizontal” are intended to additionally include “within 3-5% of” a vertical or horizontal orientation, respectively. Additionally, words of direction, such as “top,” “bottom,” “left,” “right,” “above,” and “below” are intended to relate to the equivalent direction as depicted in a reference illustration; as understood contextually from the object(s) or element(s) being referenced, such as from a commonly used position for the object(s) or element(s); or as otherwise described herein.

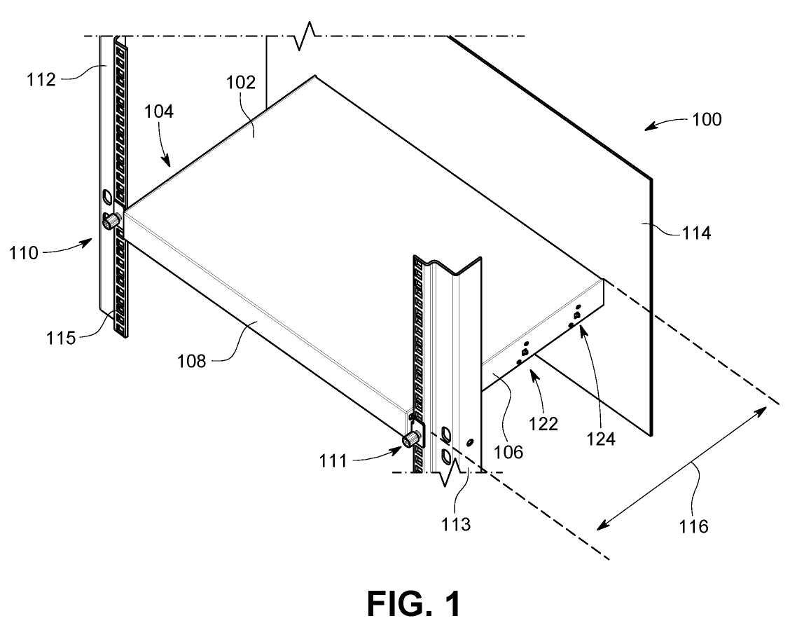

FIG. 1 is an isometric view of a chassis 102 with quick-release mounting brackets 110, 111 in a forward mounting location, according to certain aspects of the present disclosure. The chassis 102 can be any suitable chassis for any suitable computer equipment, such as a chassis for a computer server, a chassis for a storage server, a chassis for retaining accessories or other equipment, such as patch panels or power supplies, or any other suitable chassis.

The chassis 102 can be located within an enclosure 100 (partially shown) for housing the chassis 102 and any other associated equipment. The enclosure 100 can include a rear wall 114, sidewalls (not shown), a floor (not shown), a ceiling (not shown), and a front wall (not shown), although other styles of enclosures can be used. The enclosure 100 can include a left mounting post 112 and a right mounting post 113 securely fixed with respect to one another, and often with respect to at least the rear wall 114 of the enclosure 100. The distance between the mounting posts 112, 113 (e.g., a front edge or rear edge of the mounting posts 112, 113) and the rear wall 114 can be referred to as a clearance depth 116. Generally, the only traditional chassis that would be able to be mounted in the enclosure 100 are those that require a depth equal to or below the clearance depth 116.

Each mounting post 112, 113 can include multiple openings 115 for receiving screws, bolts, or other fasteners to secure rack-mountable devices to the mounting posts 112, 113. Corresponding openings 115 on the left and right mounting posts 112, 113 can define a “slot” or mounting location for a chassis 102. In other words, a chassis 102 may be mounted to the left and right mounting posts 112, 113 in a variety of locations up and down the left and right mounting posts 112, 113 by using any corresponding openings 115 (e.g., openings at the same vertical height) on the left and right mounting posts 112, 113.

As used herein, the terms “left” and “right” are intended to indicate a first side and a second side, and may be interchangeable as appropriate. For example, while the left mounting post 112 and right mounting posts 113 are towards the left and right sides of FIG. 1, respectively, when viewing the mounting posts 112, 113 from the rear wall 114, the left mounting post 112 and right mounting post 113 would seem to be towards the viewer’s right and left, respectively. Such a viewer may interchange right and left to fit that viewer’s frame of reference, changing all right and left descriptors as appropriate.

The chassis 102 can include a front wall 108, a left sidewall 104, a right sidewall 106, and a rear wall (not shown). The right sidewall 106 can include a number of mounting locations, such as a first mounting location (not visible), to which the right mounting bracket 111 is attached, a second mounting location 122, and a third mounting location 124. As described herein, the right mounting bracket 111 can be removed from the first mounting location and installed in the second mounting location 122 or third mounting location 124 with ease. Likewise, the left sidewall 104 includes complementary mounting locations for receiving the left mounting bracket 110. Any number of mounting locations can be present on a sidewall, and at any suitable depth along the sidewall.

While described as being used to secure chassis to enclosures, aspects and features of the present disclosure can be equally used to secure chassis to non-enclosed mounting posts 112, 113.

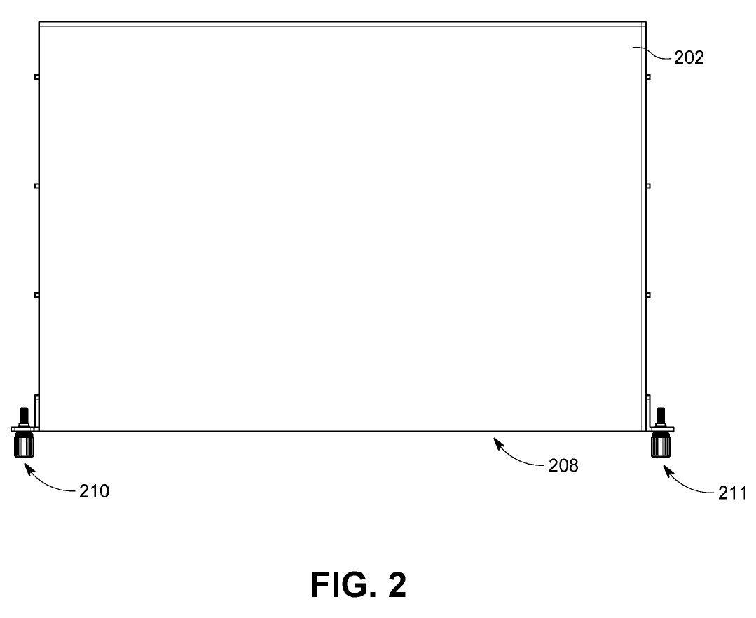

FIG. 2 is a top view of a chassis 202 with quick-release mounting brackets 210, 211 in a forward mounting location, according to certain aspects of the present disclosure. Chassis 202 can be chassis 102 of FIG. 1 and the forward mounting location can be the first mounting location of FIG. 1. In the forward mounting location, the left mounting bracket 210 and right mounting bracket 211 are positioned near the front of the chassis 202. In some cases, the front faces of the mounting brackets 210, 211 are coplanar or approximately coplanar with the front face 208, although that need not always be the case. Generally, mounting brackets 210, 211 installed in this forward mounting location allow the chassis 202 to be mounted in the same way as a traditional rack-mountable chassis (e.g., a chassis with permanent mounting brackets).

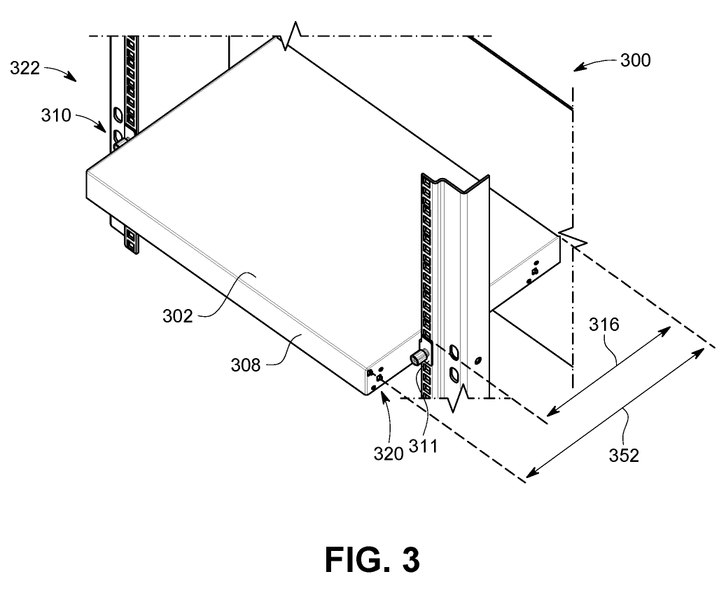

FIG. 3 is an isometric view of a chassis 302 with quick-release mounting brackets 310, 311 in a second mounting location 322, according to certain aspects of the present disclosure. Chassis 302 can be the same as or similar to chassis 102 of FIG. 1 after relocation of the mounting brackets 310, 311 to the second mounting location 322.

In the second mounting location 322, the left mounting bracket 310 and right mounting bracket 311 are each positioned further from the front wall 308 than if they were in the first mounting location 320. Thus, even though the chassis 302 has a chassis depth 352 that is greater than the clearance depth 316, the chassis 302 is still able to be mounted in enclosure 300. In some cases, the chassis depth 352 can be defined as a distance between a front wall 328 and a rear wall of the chassis 302. In some cases, the chassis depth 352 can be considered a distance from the front wall 328 to the end of a connector or other feature extending from the rear wall of the chassis 302. In some cases, the chassis depth 352 can be considered a distance from the front wall 328 past the rear wall of the chassis 302 by a distance necessary or recommended to ensure proper access to or operation of the equipment within the chassis 302 (e.g., an actual depth of the chassis 302 plus a buffer distance necessary for proper airflow through the chassis 302, for cable routing behind the chassis 302, and/or for cable access behind the chassis 302.

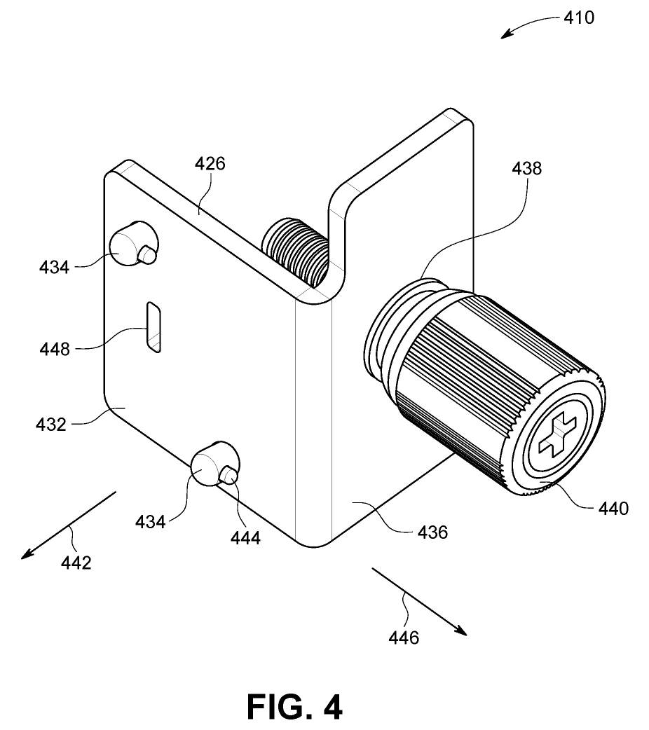

FIG. 4 is an isometric view of a quick-release mounting bracket 410, according to certain aspects of the present disclosure. The mounting bracket 410 can be the same as or similar to a right mounting bracket 111 of FIG. 1.

The mounting bracket 410 can include a bracket body 426, which can be made from a piece of bent or folded sheet metal, although that need not always be the case. The bracket body 426 includes a chassis-contacting face 432, which contacts the chassis when the mounting bracket 410 is installed on a chassis, and an outward face 436, which often faces outwards (e.g., away from a rear wall of an enclosure or away from mounting posts) when used to secure a chassis in an enclosure.

One or more studs 434 extend from the chassis-contacting face 432 in a lateral direction 442. Each stud 434 includes a detent 444 that is biased (e.g., via a spring or other suitable mechanism) to move to an extended position, but can be pushed into a retracted position (e.g., at least partially retracted into the body of the stud 434) with sufficient force. The detent 444 is generally oriented to extend and retract in a retraction direction 446 that is generally horizontal and parallel to chassis-contacting face 432, although that need not always be the case. The body of the stud 434 can be formed with or coupled to the bracket body 426 using any suitable technique, such as welding, riveting or rivet-like attachment (e.g., using deformation to secure the stud 434 to the bracket body 426), or the like. While studs 434 are depicted with a single detent 444 each, in some cases a stud 434 can include multiple detents. Such detents can be arranged in any suitable arrangement, such as colinear, although that need not always be the case. The detent 444 can be a ball detent, although that need not always be the case.

The location of the stud(s) 434 on the chassis-contacting face 432 can be selected to provide strong support for the chassis against vertical, horizontal, or rotational forces (e.g., rotation about an axis perpendicular to the chassis-contacting face 432). In the example depicted in FIG. 4, two studs 434 are used, including a first stud positioned in an upper half and rearward half of the chassis-contacting face 432 (e.g., the stud 434 depicted furthest to the left in FIG. 4), and a second stud positioned in a lower half and forward half of the chassis-contacting face 432 (e.g., the stud 434 depicted furthers to the right in FIG. 4). In other cases, multiple studs can be vertically aligned, horizontally aligned, or placed otherwise. In some cases, studs can be arranged such that a single style of mounting bracket 410 can be used on either side of a chassis by simply inverting the mounting bracket 410 in one’s hand.

A guide slot 448 can be located in the chassis-contacting face 432. The guide slot 448 can be a full opening, as depicted in FIG. 4, or simply a sufficiently deep recess (e.g., without passing entirely through the bracket body 426). The guide slot 448 can receive a guide flange, thus facilitating alignment of the mounting bracket 410, and more specifically the studs 434, with the mounting location of the chassis. The guide slot 448 can be elongated such that a corresponding guide flange cannot enter the guide slot 448 unless the mounting bracket 410 is level with respect to the chassis.

The mounting bracket 410 can include an aperture 438 for receiving a mounting screw 440. The mounting screw 440 can secure the mounting bracket 410 to a mounting post (e.g., a mounting post of an enclosure). In some cases, the mounting screw 440 is captively held within the aperture 438 such that it spins freely within and does not fall out of the aperture 438.

In some cases, a mirrored version of the mounting bracket 410 can be used for an opposite side of a chassis (e.g., as left mounting bracket 110 of FIG. 1). In some cases, studs 434 can be positioned such that a single mounting bracket 410 can be used for either side of a chassis (e.g., by positioning studs 434 along a vertical centerline of the chassis-contacting face 432.

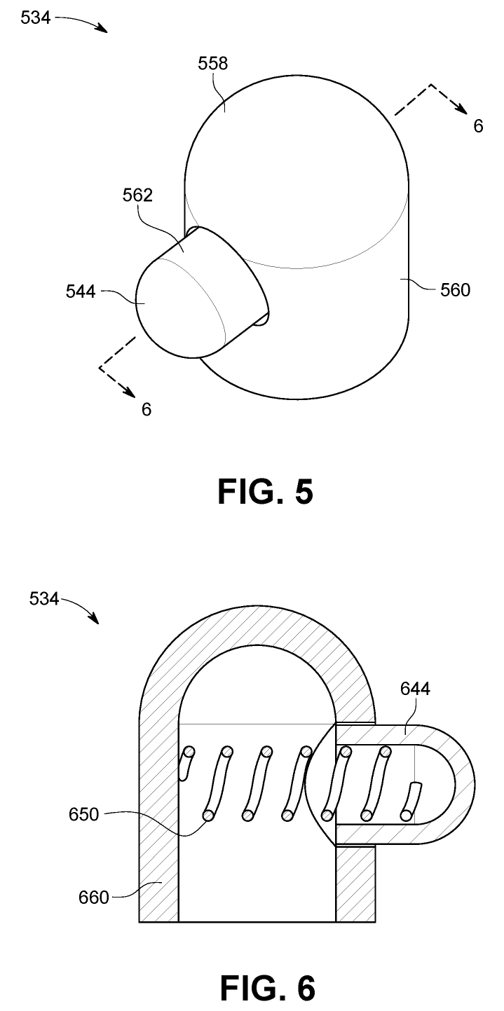

FIG. 5 is a partial view of a stud 534 of a quick-release mounting bracket, according to certain aspects of the present disclosure. The stud 534 can be the same as or similar to stud 434 of FIG. 4.

Stud 534 includes a stud body 660 ending in a distal end 558. The distal end 558 can be rounded or semi-spherical in shape, although that need not always be the case. The detent 544 extends from stud body 660 in a direction that is generally perpendicular to the stud, which can be defined by the center axis of the stud body 660.

The detent 544 can include a rounded (e.g., as shown), chamfered, or otherwise angled end positioned distally from a straight detent body 562. The straight detent body 562 can contact the sidewall of a chassis to help keep the stud positioned within the chassis when no or mild force (e.g., force from general handling of the chassis) is applied. The rounded, chamfered, or otherwise angled end of the detent 544 can facilitate retraction of the detent 544 into the stud body 560 when more force (e.g., force from intentional pulling of the mounting bracket away from the chassis) is applied.

FIG. 6 is a cutaway side view of the stud 534 of FIG. 5 taken along line 6:6, according to certain aspects of the present disclosure. As seen in FIG. 6, the detent 544 is depicted in an extended position, biased in place by a spring 650. In some cases, other biasing mechanisms that allow the detent 644 to retract but bias it towards an extended position can be used, such as a non-coil spring (e.g., a flat springs), magnetic repulsion, pneumatic compression, or the like.

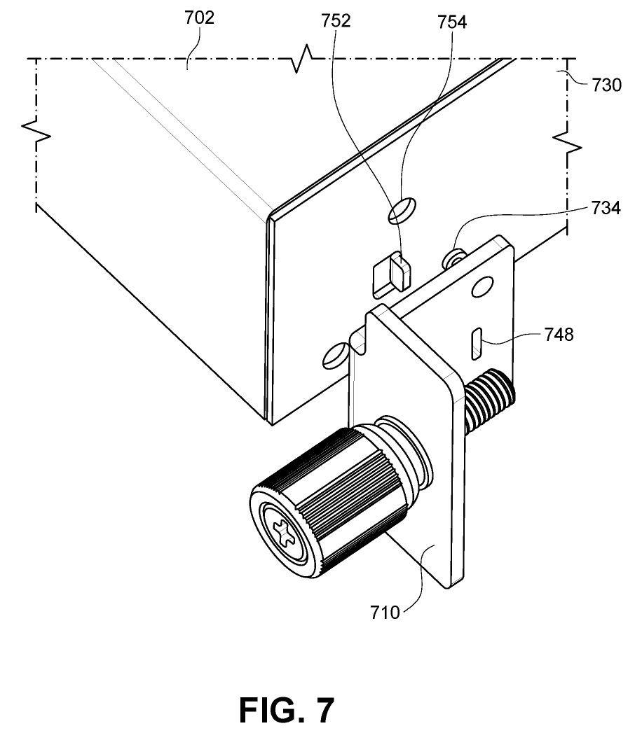

FIG. 7 is an isometric partial view of a quick-release mounting bracket 710 aligned for insertion into a chassis 702, according to certain aspects of the present disclosure. The mounting bracket 710 and chassis 702 can be the same as or similar to mounting bracket 111 and chassis 102 of FIG. 1.

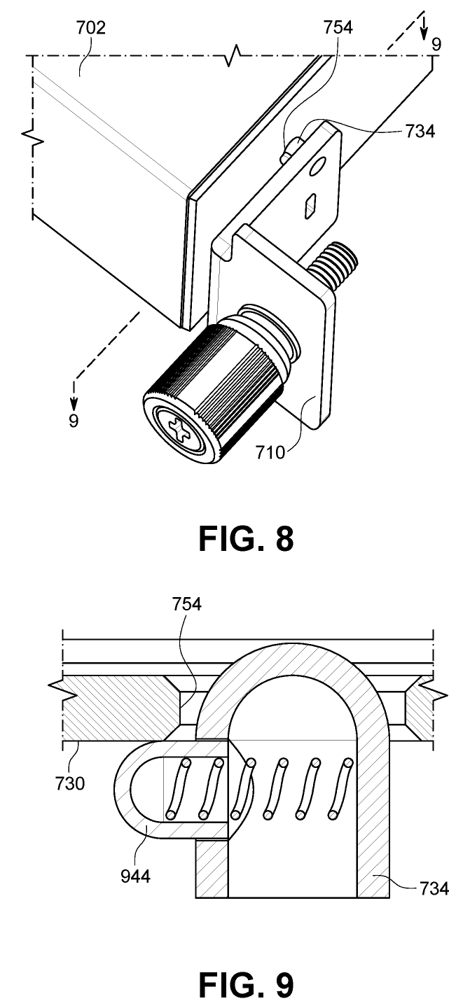

The mounting bracket 710 includes studs 734 and a guide slot 748 that are aligned with corresponding openings 754, also known as stud openings, and a guide flange 752 of the sidewall 730 of the chassis 702. As the mounting bracket 710 is moved towards the chassis 702, the guide flange 752 will enter the guide slot 748, thus ensuring the mounting bracket 710 remains aligned during further movement towards the chassis 702. Further movement towards the chassis 702 will cause the studs 734 of the mounting bracket 710 to enter the openings 754 of the chassis 702, as seen in FIGS. 8-9.

FIG. 8 is an axonometric partial view of the mounting bracket 710 of FIG. 7 with studs 734 initially inserted into the chassis 702, according to certain aspects of the present disclosure.

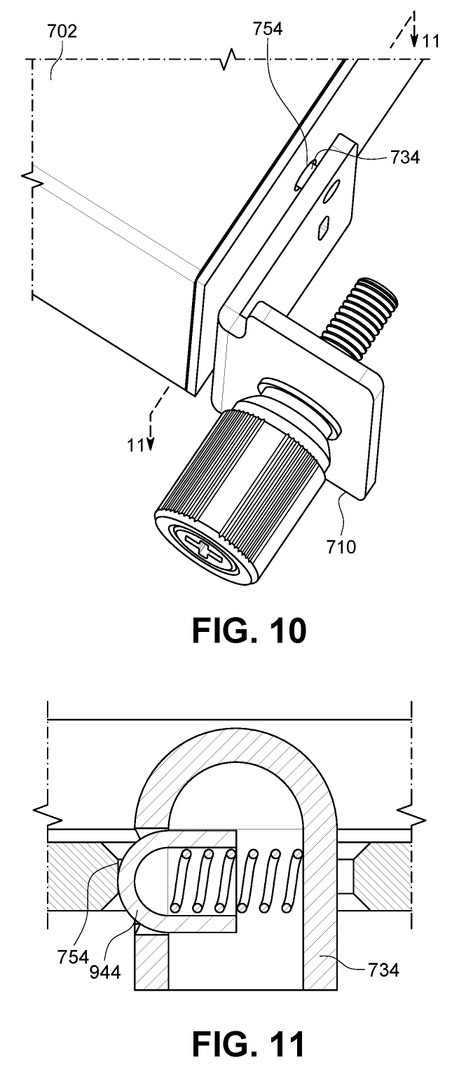

FIG. 9 is a cutaway top view of stud 734 of FIG. 8 taken along line 9:9, according to certain aspects of the present disclosure. As the stud 734 is initially inserted into the opening 754, the detent 944 comes in contact with the sidewall 730. The opening 754 includes chamfers or other angles or similar features that can interact with the detent 944 to compress the detent into the body of the stud 734 as the stud 734 is inserted further into the opening 754, as depicted in FIGS. 10-11. Similar chamfers or other angles or similar features are located at an internal side of the opening 754 to likewise compress the detent into the body of the stud 734 when an already inserted stud 734 is pulled out of the opening 754.

FIG. 10 is an axonometric partial view of the quick-release mounting bracket 710 of FIG. 8 substantially inserted into the chassis 702, according to certain aspects of the present disclosure.

FIG. 11 is a cutaway top view of the stud 734 of FIG. 10 taken along line 11:11, according to certain aspects of the present disclosure. In this substantially inserted state, the stud 734 is inserted sufficiently into the opening 754 such that the detent 944 is compressed into the body of the stud 734, thus permitting the stud 734 to be inserted into the opening 754.

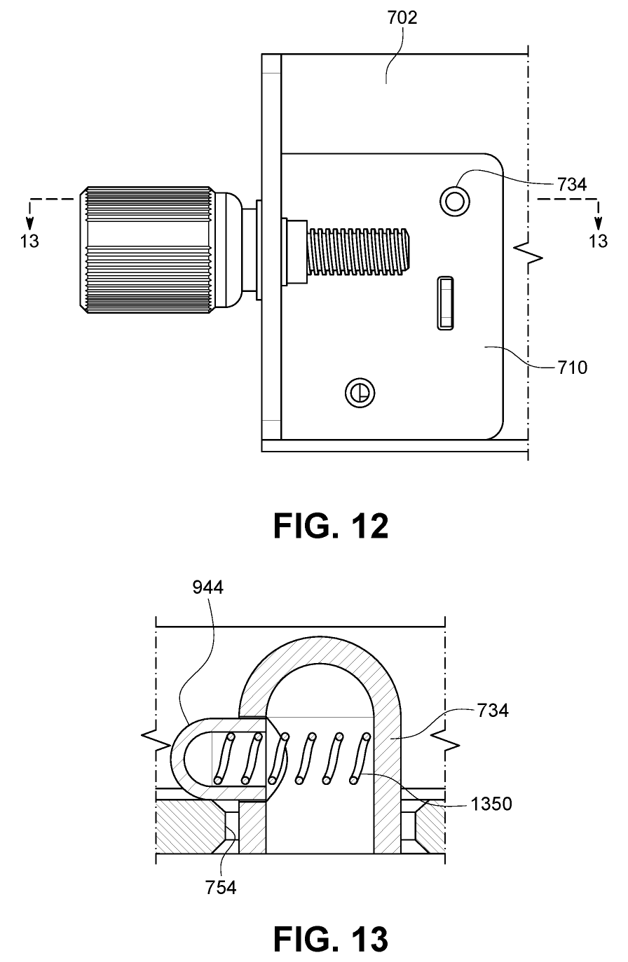

FIG. 12 is a side view of the mounting bracket 710 of FIG. 10 after the studs 734 have been fully inserted into the chassis 702, according to certain aspects of the present disclosure.

FIG. 13 is a cutaway top view of the stud 734 of FIG. 12 taken along line 13:13, according to certain aspects of the present disclosure. The stud 734 has been fully inserted into the opening 754, thus permitting the detent 944 to move back out to its extended position due to the biasing force of the internal biasing device (e.g., spring 1350).

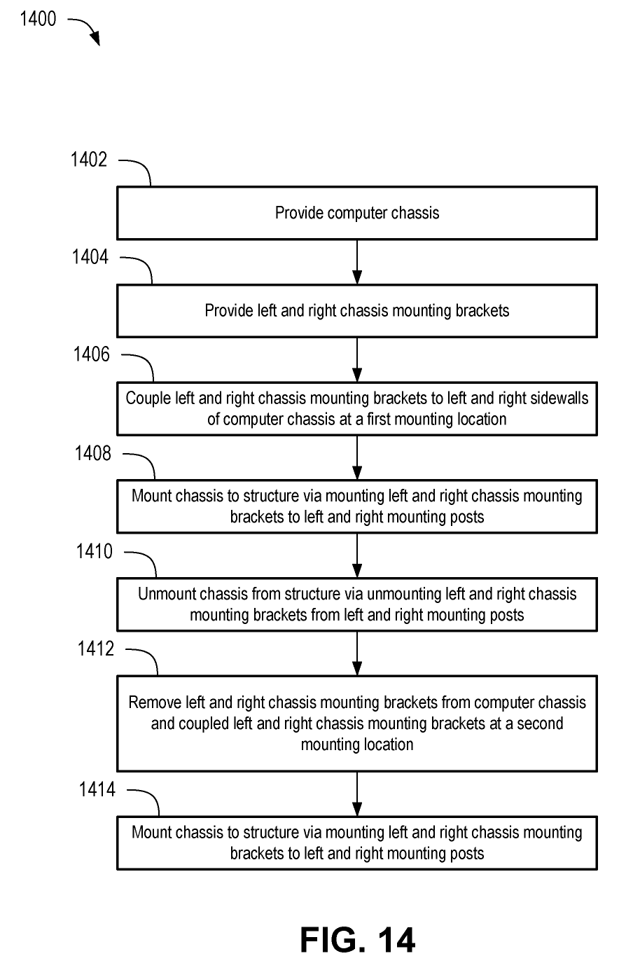

FIG. 14 is a flowchart depicting a process 1400 for using quick-release mounting brackets with a computer chassis, according to certain aspects of the present disclosure. At block 1402, a computer chassis is provided. The computer chassis can be any suitable computer chassis, such as chassis 102 of FIG. 1.

At block 1404, left and right chassis mounting brackets can be provided. Left and right chassis mounting brackets can be the same as or similar to left and right mounting brackets 110, 111 of FIG. 1, respectively.

At block 1406, the left and right chassis mounting brackets can be coupled to the left and right sidewalls of the computer chassis, respectively, at a first mounting location. Coupling a mounting bracket can include aligning the studs of the mounting bracket with corresponding openings of the sidewall, then moving the mounting bracket towards the chassis until the studs of the mounting bracket are fully inserted into the corresponding openings of the sidewall. In this state, the mounting bracket will be retained by the chassis due to the detents of the studs moving to their extended positions while within the chassis. The mounting brackets can be uncoupled from the chassis by pulling the mounting brackets away from the chassis with sufficient force to cause the detents to move to their retracted position, thus releasing the studs from the corresponding openings of the sidewall.

At block 1408, the chassis is mounted to a structure (e.g., mounted within an enclosure) by mounting the left and right chassis mounting brackets to left and right mounting posts, respectively. Mounting a mounting bracket to a mounting post includes screwing a mounting screw or applying another appropriate fastener to secure the mounting bracket to the mounting post. When the chassis is mounted to the structure, the fixed nature of the mounting posts with respect to one another ensures the mounting brackets cannot be pulled out of the chassis.

At block 1410, the chassis is unmounted from the structure by unmounting the left and right chassis mounting brackets from the left and right mounting posts, respectively. Unmounting a mounting bracket from a mounting post includes unscrewing the mounting screw or otherwise removing any other appropriate fastener used to secure the mounting bracket to the mounting post. When the chassis is unmounted from the structure, the mounting brackets are free to be pulled out and away from the chassis.

At block 1412, the left and right chassis mounting brackets are removed from the chassis by pulling the mounting brackets outwards and away from the chassis. The mounting brackets are then coupled to the chassis at a second mounting location. The second mounting location is further from or closer to the front of the chassis than the first mounting location.

At block 1414, the chassis is mounted to the structure by mounting the left and right chassis mounting brackets to left and right mounting posts, respectively. Because of the new location of the mounting brackets, the chassis itself sits at a different depth in front of or behind the mounting posts.

Although the disclosed embodiments have been illustrated and described with respect to one or more implementations, equivalent alterations and modifications will occur or be known to others skilled in the art upon the reading and understanding of this specification and the annexed drawings. In addition, while a particular feature of the invention may have been disclosed with respect to only one of several implementations, such feature may be combined with one or more other features of the other implementations as may be desired and advantageous for any given or particular application.

While various embodiments of the present disclosure have been described above, it should be understood that they have been presented by way of example only, and not limitation. Numerous changes to the disclosed embodiments can be made in accordance with the disclosure herein, without departing from the spirit or scope of the disclosure. Thus, the breadth and scope of the present disclosure should not be limited by any of the above described embodiments. Rather, the scope of the disclosure should be defined in accordance with the following claims and their equivalents.

What is claimed is:

1. A chassis mounting bracket, comprising:
a bracket body having a front wall and a side wall, the side wall having a chassis-contacting face;
an aperture in the front wall for receiving a mounting screw; and
a plurality of studs extending from the chassis-contacting face in a lateral direction that is perpendicular to the chassis-contacting face, each of the plurality of studs having a detent movable between a retracted position and an extended position, the detent being biased towards the extended position.

2. The chassis mounting bracket of claim 1, further comprising a guide slot in the side wall for receiving a guide flange of a chassis, wherein the guide slot is positioned with respect to the plurality of studs such that when the guide slot is aligned to receive the guide flange of the chassis each of the plurality of studs is aligned to be received by corresponding stud openings in the chassis.

3. The chassis mounting bracket of claim 1, wherein the plurality of studs includes a first stud extending from a top half of the chassis-contacting face of the side wall and a second stud extending from a bottom half of the chassis-contacting face of the side wall.

4. The chassis mounting bracket of claim 3, wherein the plurality of studs includes a first stud extending from a front half of the chassis-contacting face of the side wall and a second stud extending from a rear half of the chassis-contacting face of the side wall.

5. The chassis mounting bracket of claim 1, wherein each of the plurality of studs moves between the retracted position and the extended position along a retraction direction that is perpendicular to the lateral direction.

6. The chassis mounting bracket of claim 1, wherein at least one stud of the plurality of studs includes a second detent movable between a second retracted position and a second extended position, the second detent being biased towards the second extended position.

7. The chassis mounting bracket of claim 6, wherein the detent and the second detent are arranged colinearly.

8. The chassis mounting bracket of claim 1, wherein the detent is a ball detent.

9. The chassis mounting bracket of claim 1, wherein the detent is spring-biased towards the extended position.

10. The chassis mounting bracket of claim 1, wherein the mounting screw is captively secured within the aperture.

11. The chassis mounting bracket of claim 1, wherein each detent is shaped to move to the retracted position when contacting a periphery of a stud opening in a chassis and return to the extended position when fully inserted within the stud opening.

12. A computer chassis mounting system, comprising:
a computer chassis having a first sidewall opposite a second sidewall;
a first mounting location of the computer chassis having a first set of mounting apertures in the first sidewall positioned opposite a corresponding second set of mounting apertures in the second sidewall; and
a pair of chassis mounting brackets, each of the pair of chassis mounting brackets being the chassis mounting bracket of claim 1, wherein a first chassis mounting bracket of the pair of chassis mounting brackets is coupled to the computer chassis at the first set of mounting apertures, and wherein a second chassis mounting bracket of the pair of chassis mounting brackets is coupled to the computer chassis at the second set of mounting apertures.

13. The computer chassis mounting system of claim 12, further comprising a first mounting post and a second mounting post, each of the first mounting post and the second mounting post having a plurality of corresponding vertically spaced-apart apertures, wherein the mounting screw of the first chassis mounting bracket is coupled to the first mounting post at a first aperture of the plurality of vertically spaced-apart apertures, and wherein the mounting screw of the second chassis mounting bracket is coupled to the second mounting post at a second aperture of the plurality of vertically spaced-apart apertures, the first aperture and the second aperture being at an equal height.

14. The computer chassis mounting system of claim 12, further comprising:
a second mounting location of the computer chassis spaced apart from the first mounting location, the second mounting location having a third set of mounting apertures in the first sidewall positioned opposite a corresponding fourth set of mounting apertures in the second sidewall.

15. The computer chassis mounting system of claim 14, wherein the second mounting location is positioned between a front wall of the computer chassis and the first mounting location.

16. A method for mounting a computer chassis, comprising:
providing a computer chassis having:
a left sidewall opposite a right sidewall; and
a first mounting location having a left set of mounting apertures in the left sidewall positioned opposite a corresponding right set of mounting apertures in the right sidewall;
providing a left chassis mounting bracket and a right chassis mounting bracket, each of the left chassis mounting bracket and the right chassis mounting bracket including:
a bracket body having a front wall and a side wall, the side wall having a chassis-contacting face;
an aperture in the front wall for receiving a mounting screw; and
a plurality of studs extending from the chassis-contacting face in a lateral direction that is perpendicular to the chassis-contacting face, each of the plurality of studs having a detent movable between a retracted position and an extended position, the detent being biased towards the extended position;
coupling the left chassis mounting bracket to the left sidewall of the computer chassis at the first mounting location by inserting the plurality of studs of the left chassis mounting bracket into the left set of mounting apertures; and
coupling the right chassis mounting bracket to the right sidewall of the computer chassis at the first mounting location by inserting the plurality of studs of the right chassis mounting bracket into the right set of mounting apertures.

17. The method of claim 16, wherein inserting the plurality of studs of the left chassis mounting bracket into the left set of mounting apertures and inserting the plurality of studs of the right chassis mounting bracket into the right set of mounting apertures each includes, for each stud of the respective plurality of studs:
retracting the respective detent to the retracted position in response to contacting the respective detent with a respective periphery of the respective mounting aperture during initial insertion of the respective stud into the respective mounting aperture; and
returning the respective detent to the extended position in response to fully inserting the respective stud into the respective mounting aperture.

18. The method of claim 17, wherein the first mounting location further includes a left guide flange and a right guide flange, wherein the left chassis mounting bracket includes a left guide slot, wherein the right chassis mounting bracket includes a right guide slot, wherein inserting the plurality of studs of the left chassis mounting bracket into the left set of mounting apertures includes aligning the left guide flange with the left guide slot, and wherein inserting the plurality of studs of the right chassis mounting bracket into the right set of mounting apertures includes aligning the right guide flange with the right guide slot.

19. The method of claim 16, wherein the computer chassis further includes a second mounting location having a second left set of mounting apertures in the left sidewall positioned opposite a corresponding second right set of mounting apertures in the right sidewall, the method further comprising:
removing the left chassis mounting bracket from the left sidewall of the computer chassis;
removing the right chassis mounting bracket from the right sidewall of the computer chassis;
coupling the left chassis mounting bracket to the left sidewall of the computer chassis at the second mounting location by inserting the plurality of studs of the left chassis mounting bracket into the second left set of mounting apertures; and
coupling the right chassis mounting bracket to the right sidewall of the computer chassis at the second mounting location by inserting the plurality of studs of the right chassis mounting bracket into the second right set of mounting apertures.

20. The method of claim 19, the left chassis mounting bracket including a left captive screw, the right chassis mounting bracket including a right captive screw, the method further comprising:
mounting the chassis to a structure, the structure supporting a left mounting post and a right mounting post, mounting the chassis to the structure including securing the left chassis mounting bracket to the left mounting post via the left captive screw and securing the right chassis mounting bracket to the right mounting post via the right captive screw.
